(19) United States
(12) Patent Application Publication
(10) Pub. No.: US 2026/0101510 A1
(43) Pub. Date: Apr. 9, 2026

(54) 3D NAND COMINGLED WORDLINE CONTACT AND THROUGH ARRAY VIA AREA

(71) Applicant: Intel NDTM US LLC, Santa Clara, CA (US)

(72) Inventors: Kwame Nkrumah Eason, East Palo Alto, CA (US); Hoon KOH, San Jose, CA (US); Liu LIU, Dalian (CN); Zengtao LIU, Eagle, ID (US); Ebony MAYS, Morgan Hill, CA (US); Yuji TAKAHASHI, San Jose, CA (US); Deepak THIMMEGOWDA, Fremont, CA (US); Baosuo ZHOU, Redwood City, CA (US); Md Rezaul Karim Nishat, Santa Clara, CA (US)

(21) Appl. No.: 19/114,758

(22) PCT Filed: Oct. 27, 2022
(86) PCT No.: PCT/CN2022/127892

§ 371 Date: Mar. 24, 2025

(51) Int. Cl. H10B 43/27; H10B 41/27

(52) U.S. Cl. CPC H10B 43/27; H10B 41/27

(57) ABSTRACT

Systems, apparatuses, and methods may provide for technology that arranges a wordline access structure for memory devices. The memory device includes a memory array and a memory block coupled to the memory array. The memory block includes a plurality of wordlines penetrating through a plurality of decks of a non-volatile memory structure. A plurality of through array vias penetrate through the plurality of decks, where the plurality of through array vias and the plurality of wordlines are comingled in a shared wordline access structure area. Additionally, or alternatively, the memory device is manufactured based on forming multi-level via holes penetrating through a plurality of decks of a non-volatile memory structure of a memory device based on wordline contact patterning. A metal film is deposited to fill the via holes to form wordline contacts.

### TECHNICAL FIELD

Embodiments generally relate to memory structures. More particularly, embodiments relate to a layout of wordline contacts and though array vias utilized in 3D NAND memory structures.

### BACKGROUND

NAND-type flash memory (“NAND memory”) may be organized into multiple cells, with each cell containing one or more bits of data and being accessible through an array of bit lines (columns) and word lines (rows). With the increase of number of tiers or word lines (WL) in 3D NAND in every generation, the number of WL contacts is also going up, requiring more routing paths to hook up the word line contacts to corresponding string driver complementary metal-oxide-semiconductor (CMOS) devices.

### BRIEF DESCRIPTION OF THE DRAWINGS

The various advantages of the embodiments will become apparent to one skilled in the art by reading the following specification and appended claims, and by referencing the following drawings, in which:

FIG. 1 is a block diagram of an example of an existing multi-deck non-volatile memory device;

FIG. 2 illustrates an example side view diagram of a memory die according to an embodiment;

FIG. 3 is a block diagram of an example existing memory device with a sequential staircase structure;

FIG. 4 is a block diagram of another example existing memory device with a parallel staircase structure;

FIGS. 5A-5B is a cross sectional diagram comparing an existing wordline contact formation (FIG. 5A) to an example wordline contact formation according to an embodiment (FIG. 5B);

FIG. 6 is a cross sectional diagram of a multi-level wordline contact patterning according to an embodiment;

FIGS. 7A-7B is a top view and cross sectional diagram comparing an existing wordline contact formation (FIG. 7A) to an example wordline contact formation according to an embodiment (FIG. 7B);

FIG. 8 is a flowchart of an example of another method of forming a memory device according to an embodiment;

FIG. 9 is an illustration of an example of a semiconductor package apparatus according to an embodiment; and

FIG. 10 is a block diagram of an example of a performance-enhanced computing system according to an embodiment.

### DESCRIPTION OF EMBODIMENTS

As described above, NAND-type flash memory (“NAND memory”) may be organized into multiple cells, with each cell containing one or more bits of data and being accessible through an array of bit lines (columns) and word lines (rows). 3D NAND memory has vertical channels (column-shape) and horizontal WL (plate-shape) in Cell array. Each wordline (WL) is connected to WL drivers through WL contacts. With the increase of number of tiers or word lines (WL) in 3D NAND in every generation, the number of word line contacts is also going up, requiring more routing paths to hook up the word line contacts to corresponding string driver complementary metal-oxide-semiconductor (CMOS) devices.

Some existing WL contact formation methods typically include staircase (SC) formation, oxide gap fill, and chemical mechanical polishing (CMP), WL contact patterning, and metal fill, and additional chemical mechanical polishing (CMP). This is a lengthy flow that contains many process steps. Therefore, the production cost of WL contact formation is significant in 3D NAND memory fabrication. There is no known-good-solution for this problem. Existing 3D NAND products typically have a common WL contacts formation method, which is a staircase process. Disadvantageously, the production cost of such a staircase formation keeps expanding, as the number of steps and process time grows with increasing number of tiers.

Some existing WL contact formation methods typically include WL contacts being placed on a pre-formed staircase. Each WL typically has a connection only to the designated WL and keeps enough distance away from other WLs to avoid short-circuits. However, because of the process variation (e.g., etch bias, layer-to-layer overlay error, cumulative process error during trim/etch, etc.), a WL contact can be too close to other WLs, causing dielectric breakdown of the insulator in-between, with existing staircase (SC) processes Accordingly, with existing staircase (SC) processes, yield loss is negatively impacted by such short-circuits between WL contacts and WLs.

Disadvantageously, with existing staircase (SC) processes, wordline (WL) contacts and through array via (TAV) are typically locate in different region. WL contacts are formed in SC, and TAVs will be formed outside the SC. Those WL contacts and TAVs should be connected through a metal layer that is above the array. As the number of WL is increasing, the metal routing may continue to get more congested and challenging. This is one of the limitations of WL contacts and TAV placement in WL hookup, with existing staircase (SC) processes, and the less flexibility of the layout makes the die scaling more challenging.

Disadvantageously, with existing staircase processes, an expansion of the space between WL contacts typically increases the die size, reducing the chance of short-circuits between WL contacts and WLs. Further, with existing staircase processes, any attempt at a random distribution of WL contacts will take a large area, expanding the die size significantly.

As will be descried in greater detail below, systems, apparatuses, and methods described herein may provide for technology that arranges a wordline access structure for memory devices. In some examples, the memory device includes a memory array and a memory block coupled to the memory array. The memory block includes a plurality of wordlines penetrating through a plurality of decks of a non-volatile memory structure. A plurality of through array vias penetrate through the plurality of decks, where the plurality of through array vias and the plurality of wordlines are comingled in a shared wordline access structure area. Additionally, or alternatively, the memory device is manufactured based on forming multi-level via holes penetrating through a plurality of decks of a non-volatile memory structure of a memory device based on wordline contact patterning. A metal film is deposited to fill the via holes to form wordline contacts.

Some implementation described herein provide a wordline contact structure that is very different from existing solutions. For example, as will be described in greater detail below, some implementation described herein provide for WL contacts structure that have a direct contact from the top of array to each wordline, without a staircase structure. Accordingly, each via may landing on each wordline directly without forming staircase structure.

Advantageously, some implementation described herein provide a cost benefit due to less process steps required. The structure does not have yield loss by WL contacts to WL being short-circuited from process formation. Also, some implementation described herein provide a complete WL contact layout flexibility, where WL contact locations can be defined by mask layout (e.g., not by a staircase formation process as in existing processes).

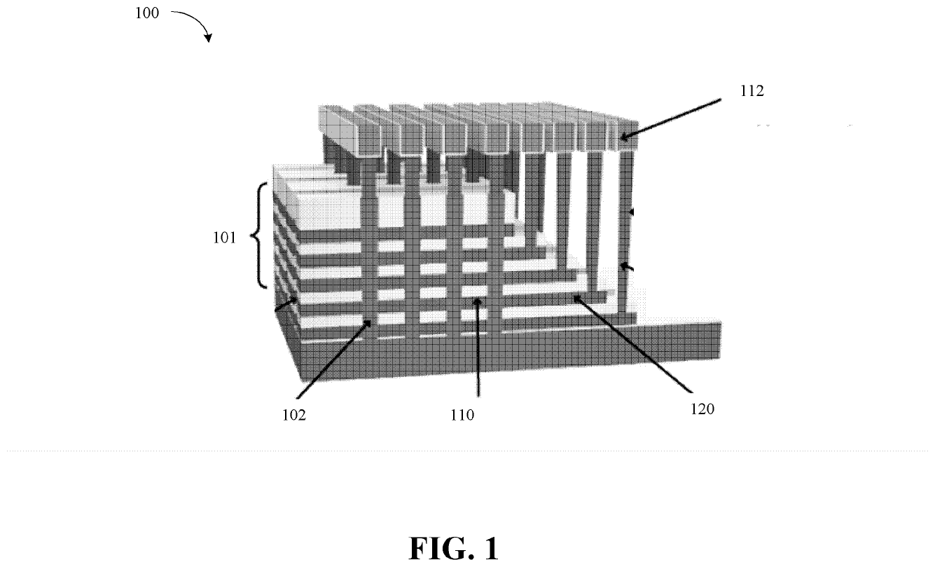

FIG. 1 is a block diagram of an example of an existing multi-deck non-volatile memory device 100. As illustrated, the memory device 100 is a multi-deck non-volatile memory device including a film stack 101 (e.g., which may be formed as one or more multi-deck memory architectures, multi-layer memory architectures, the like, or combinations thereof).

In some implementations, the film stack 101 may include an array of memory cells 102 with conductive access lines (e.g., word lines 110 and bitlines 112). For example, the memory cells 102 may include a material capable of being in two or more stable states to store a logic value.

In the illustrated example, a staircase structure 120 is utilized. However, as will be described in greater detail below, such a staircase structure 120 may be avoided in some implementations described herein.

Examples of multi-deck or multi-layer memory architectures include multi-deck memory and 3D NAND memory. Different memory technologies have adopted different terminology. For example, a deck in some memory devices typically refers to a layer of memory cell stacks that can be individually addressed. In contrast, a 3D NAND memory device is typically said to include a NAND array that includes many layers, as opposed to decks. In 3D NAND, a deck may refer to a subset of layers of memory cells (e.g., two decks of X-layers to effectively provide a 2X-layer NAND device). The term “deck” will be used throughout this disclosure to describe a layer, a tier, or a similar portion of a three-dimensional memory.

The memory device 100 may include non-volatile memory and/or volatile memory. Non-volatile memory is a storage medium that does not require power to maintain the state of data stored by the medium. In one embodiment, the memory structure is a block addressable storage device, such as those based on NAND technologies. A storage device may also include future generation non-volatile devices.

As will be described in greater detail below, systems, apparatuses and methods of some implementations herein provide for technology that arranges word line access structures for memory devices.

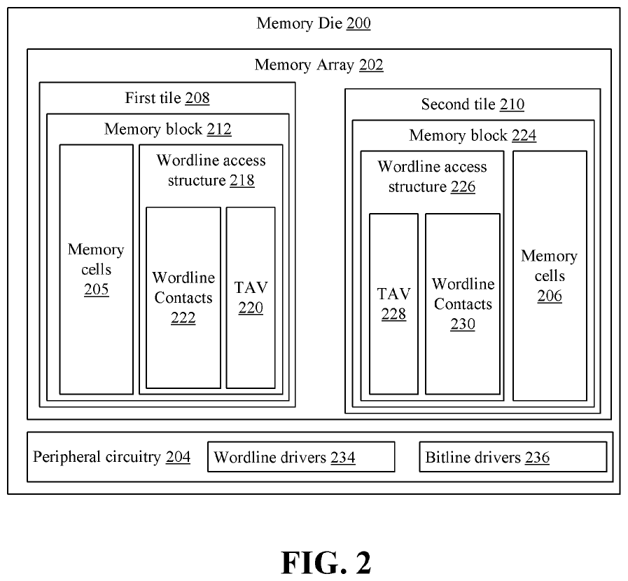

FIG. 2 illustrates a simplified example side view diagram of a memory die 200, consistent with one embodiment of the present disclosure. The memory die 200 includes a 3D flash memory architecture and utilizes a word line bridge to share word line access structures between two tiles of a memory array, according to one embodiment.

The memory die 200 includes a memory array 202 and peripheral circuitry 204, according to one embodiment. The memory array 202 includes memory cells 205 and memory cells 206 that are accessed (e.g., read/write) with the peripheral circuitry 204, according to one embodiment. The peripheral circuitry 204 is fabricated at least partially under the memory array 202 in the memory die 200, for example, using CMOS under the array fabrication techniques, according to one embodiment.

The memory array 202 is segmented into a first tile 208 and a second tile 210, according to one embodiment. Although two tiles are illustrated and described the memory array 202 may be segmented into 10's or 100's of tiles to facilitate access and operation of the memory array 202, according to one embodiment. The first tile 208 includes a memory block 212, which includes the memory cells 205 and word line access structures 218, according to one embodiment. The word line access structures 218 include through array vias 220 and wordline contacts 222, according to one embodiment. The through array vias 220 connect word lines for the memory cells 205 to the peripheral circuitry 204, under the memory array 202, according to one embodiment. The wordline contacts 222 connect the word lines of the memory cells 205 to metal contacts for connection to upper metal levels, according to one embodiment. The word line access structures 218 are illustrated disproportionately large in comparison to the memory cells 205 for illustration purposes. In practice, the memory cells 205 may occupy a significantly larger area in the memory array that the word line access structures 218, according to one embodiment.

The second tile 210 includes a memory block 224, which includes the memory cells 206 and word line access structures 226, according to one embodiment. The word line access structures 226 include through array vias 228 and wordline contacts 230, according to one embodiment. The through array vias 228 pass through the memory block 224 to couple upper metal levels to the peripheral circuitry 204, according to one embodiment. The wordline contacts 230 provides landings and/or a structure to which metal contacts connect the word lines of the memory cells 206 to upper metal levels that are on top of or above the memory array 202, according to one embodiment.

The peripheral circuitry 204 includes word line drivers 234 and bitline drivers 236 that drive word lines and bitlines for the memory array 202, according to one embodiment.

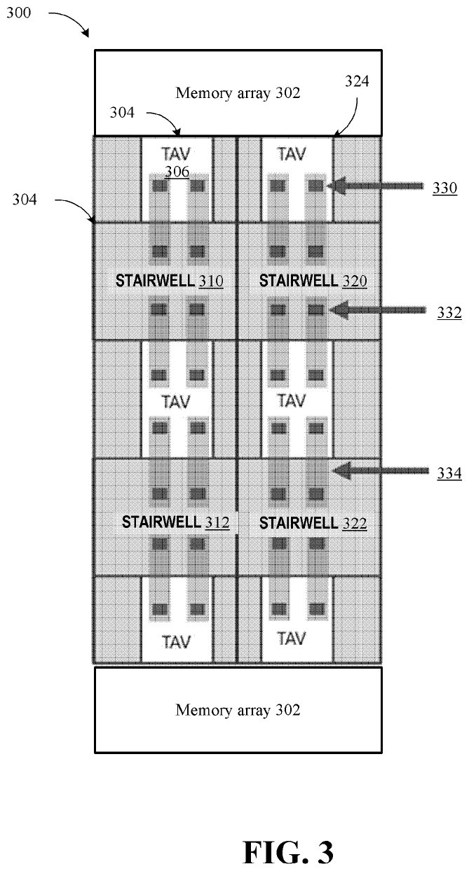

FIG. 3 is a block diagram of an example existing memory device 300 with a serial staircase structure. As illustrated, existing memory device 30 typically has one or more stair wells per memory block. Further, a stair well typically has word line contacts landing on each deck (e.g., all three decks in some implementations). Additionally, the stair wells and through array vias (TAV) are placed in serial positions.

As illustrated, the existing memory device 300 includes a memory array 302 and a memory block 304 coupled to the memory array 302. Each memory block (e.g., memory block 304 and memory block 324) is typically limited to a total of two stair wells (e.g., stair wells 310/312 for memory block 304 and stair wells 320/322 for memory block 324) per memory block.

A plurality of metal routers 334 individually connect a plurality of word line contacts 332 to a plurality of string driver contacts 330. As illustrated, an individual stair well typically has word line 332 contacts landing on each and every deck (e.g., all three decks in some implementations). Additionally, the stair wells and through array vias (e.g., TAVs 306) are placed in serial positions (e.g., where a stairwell is interspersed between each sequential pair of TAVs).

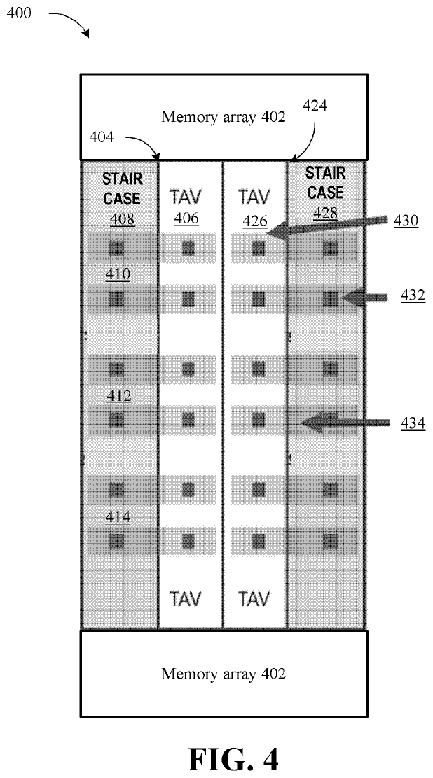

FIG. 4 is a block diagram of another example existing memory device 400 with a parallel staircase structure. As illustrated, the existing memory device 400 differs from the existing memory device 300 in several ways. The existing memory device 400 typically includes more than two stair wells (e.g., three stair wells in the illustrated example). Further, the plurality of stairwells have word line contacts that land on only one deck (e.g., one stair well per deck). Additionally, the stair wells and through array vias (TAV) are placed side-by-side in parallel position.

As illustrated, the existing memory device 400 typically includes a memory array 402 and a memory block 404 coupled to the memory array 402.

The existing memory block typically includes a first through array via area 406 and a first staircase area 408. The first staircase area 408 is coupled to a plurality of decks (e.g., Deck, 0, Deck 1, etc. of FIG. 1) and positioned adjacent to the first through array via area 406.

The first staircase area 408 includes a first stair well 410 and a second stair well 412 located contiguous to the first stair well 410. In some implementations, the first staircase area 408 comprises a third stair well 414 located contiguous to the first stair well 410 and the second stair well 412.

The first stair well 410 is typically coupled exclusively to a first one of the plurality of decks (e.g., Deck 0 of FIG. 1). In such an example, the second stair well 412 is coupled exclusively to a second one of the plurality of decks (e.g., Deck 1 of FIG. 1). The second stair well 412 is a different stair well than the first stair well 410 and the second one of the plurality of decks (e.g., Deck 1 of FIG. 1) is a different deck than the first one of the plurality of decks. (e.g., Deck 0 of FIG. 1).

The existing memory device 400 typically includes a second memory block 424 coupled to the memory array 402. The second memory block 424 includes a second through array via area 426 and a second staircase area 428. In such an example, the second staircase area 428 is coupled to the plurality of decks (e.g., Deck, 0, Deck 1, etc. of FIG. 1) and positioned adjacent to the second through array via area 426.

The first and second staircase areas 408/428 and the first and second through array via areas 406/426 may form a sandwich structure. Such a sandwich structure has the first and second staircase areas 408/428 located on an outside of the sandwich and the first and second through array via areas 406/426 positioned adjacent one another on an inside of the sandwich.

Similarly, the first and second staircase areas 408/428 and the first and second through array via areas 406/426 may extend parallel to one another and perpendicular to the memory array 402.

The first through array via area 406 typically comprise a plurality of string driver contacts 430 and the first staircase area 408 comprises a plurality of word line contacts 432. In such an example a plurality of metal routers 434 individually connect the plurality of word line contacts 432 to the plurality of string driver contacts 430. As illustrated, the plurality of metal routers 434 extend parallel to the memory array 402.

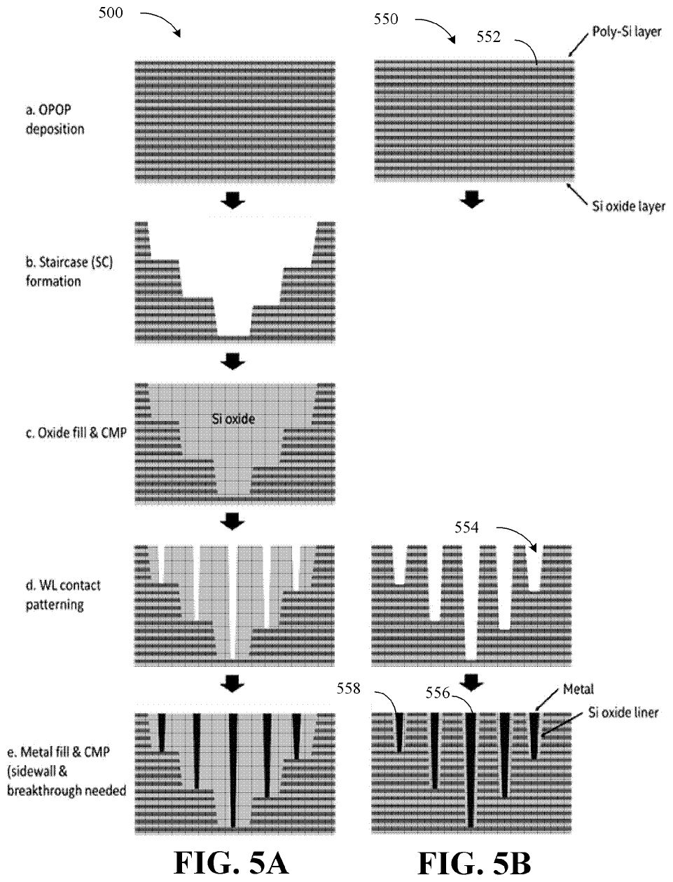

FIGS. 5A-5B is a cross sectional diagram comparing an existing wordline contact formation for a multi-deck non-volatile memory structure 500 (FIG. 5A) to an example wordline contact formation for an example multi-deck non-volatile memory structure 550 according to an embodiment (FIG. 5B).

Referring to FIG. 5A, in the existing flow, creating a film stack for the multi-deck non-volatile memory structure 500 is done by depositing multiple, thin layers of oxide/polysilicon (OPOP), or the like. OPOP layers will be removed and the top of a poly layer of each wordline (WL) will be exposed (b) for following a WL contact formation process. This formation process generally includes multiple OPOP layer etch and resist trim sequences (e.g., a staircase formation process). Then, the staircase region will be filled with oxide and planarized with CMP (c). Then wordline (WL) contact patterning (d) and metal fill (e) follow.

Referring to FIG. 5b, according to an embodiment, creating a film stack 552 for the example multi-deck non-volatile memory structure 550 is similarly done by depositing multiple, thin layers of oxide/polysilicon (OPOP), or the like. Conversely, the example process disclosed herein for example multi-deck non-volatile memory structure 550 does not undergo staircase formation operations (b) nor oxide fill operation or CMP operation (c). Via holes 554 that have approximately a 300˜2000 nm diameter will be formed in the OPOP Layer, and each hole will be stopped on each poly wordline. Then, a metal film 556 will be deposited to fill in the via holes 554, followed by CMP to get rid of residual metals. The elimination of Oxide fill and CMP process contributes to the lower cost of the implementations described herein as compared to existing staircase based process.

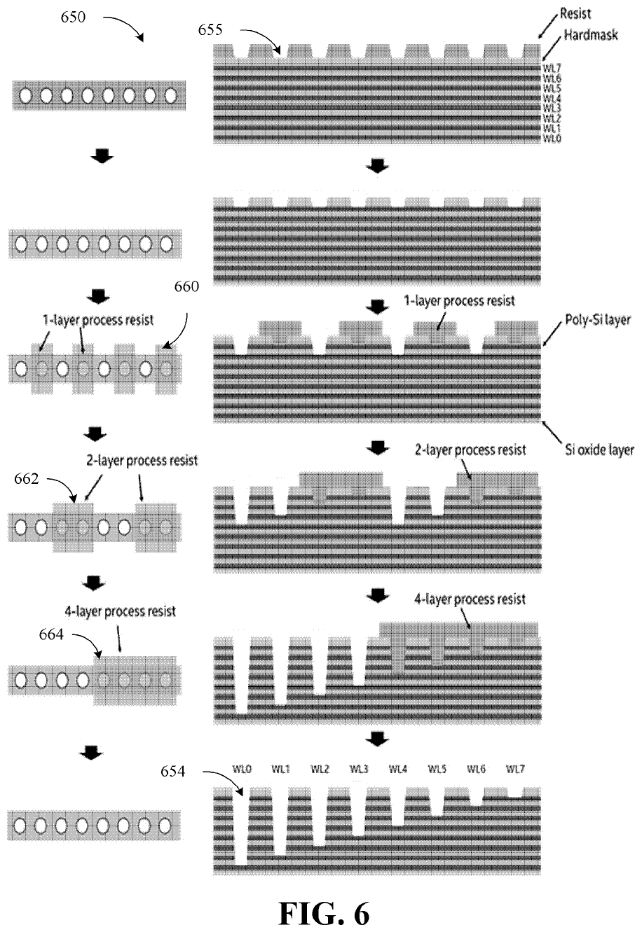

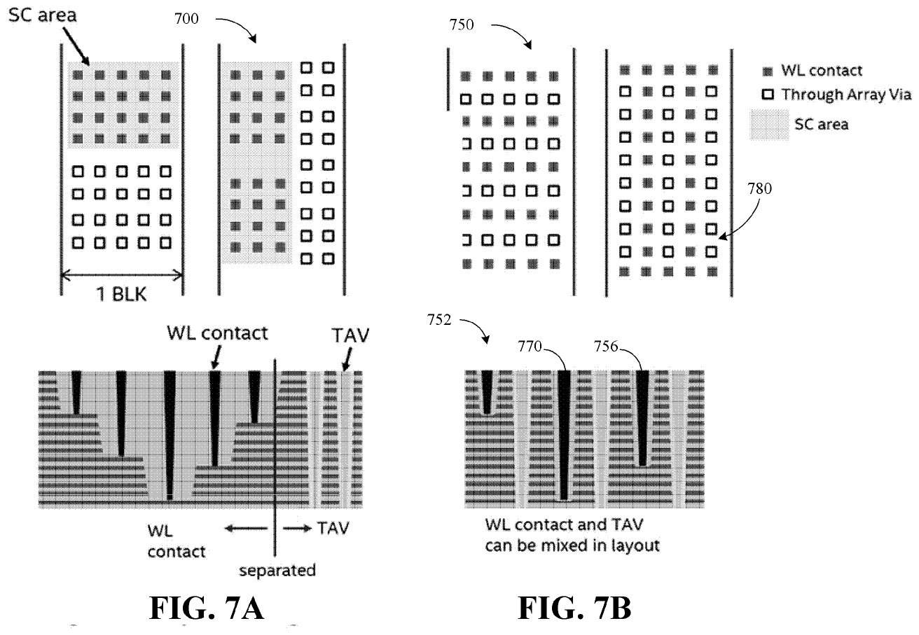

Additional details regarding the various implementations of the example multi-deck non-volatile memory structure 550 are discussed below with regard to FIGS. 6 and 7B.

FIG. 6 is a cross sectional diagram of a multi-level wordline contact patterning for an example multi-deck non-volatile memory structure 650 according to an embodiment. As illustrated, a multi-mask patterning process may be performed to form multi-level via holes 654. For example, the multi-mask pattern may cover a varying portion of wordline cavities 655 at each mask stage of the multi-mask patterning process.

In some implementations, the multi-mask patterning process further includes forming a first, second, and third, etc. process resist. For example, such a first process resist may include forming the first process resist 660 to cover a first half of the wordline cavities, where the first process resist has a first pattern that only covers every other wordline cavity; etching a first uncovered half of the wordline cavities; and removing the first process resist.

Additionally, or alternatively, such a second process resist 662 may include forming the second process resist to cover a second half of the wordline cavities, where the second process resist has a second pattern that only covers every other quad of wordline cavities; etching a second uncovered half of the wordline cavities; and removing the second process resist.

Additionally, or alternatively, such a third process resist 664 may include forming the third process resist to cover a third half of the wordline cavities, wherein the third process resist has a third pattern that only covers every other quad of wordline cavities; etching a third uncovered half of the wordline cavities; and removing the third process resist.

In operation, in the WL contact patterning step (see, e.g., step (d) of FIG. 5B), multiple masks will be introduced to process multi-level via holes, in some implementations. FIG. 6 shows one embodiment to form WL0-WL7 contacts. First, the hardmask will be deposited on top of OPOP layers and then, circle shape patterns will be engraved in that hardmask using lithography and Reactive-ion etching (RIE), for example. Each circle patten on the hardmask will become a corresponding WL contact. Then, a 1-layer process resist will cover half of WL contacts and another half of the WL contacts will be processed by a 1-layer etch. This 1-layer etch can be performed by etch-stop detection or precise time-controlled etching with a high selectivity condition, for example. Then, the resist will be removed by a dry or wet treatment. Likewise, a 2-layer process and a 4-layer process may follow. After the multi-mask patterning process (e.g., 1-layer, 2-layer, 4-layer, etc.), 8 WL contacts (WL0-WL7) are formed in the illustrated example. In general, N (N=1, 2, 3, . . . ) masks are needed to form 2^{N} WL or less contacts. For example, to make 100 WL contacts of 100 WL layers, this lithography and etch process may be repeated 7 times.

Additional details regarding the various implementations of the example multi-deck non-volatile memory structure 650 are discussed below with regard to FIG. 7B.

FIGS. 7A-7B is a top view and cross sectional diagram comparing an existing wordline contact formation for an existing multi-deck non-volatile memory structure 700 (FIG. 7A) to an example wordline contact formation for an example multi-deck non-volatile memory structure 750 according to an embodiment (FIG. 7B).

Referring to FIG. 7B, in some implementations, a memory block 752 includes a plurality of wordlines contacts 756 penetrating through a plurality of decks of example multi-deck non-volatile memory structure 750. Additionally, or alternatively, a plurality of through array vias 770 penetrate through the plurality of decks, where the plurality of through array vias 770 and the plurality of wordlines 756 are comingled in a shared wordline access structure area 780.

In some examples, the plurality of through array vias 770 and the plurality of wordlines 756 are comingled so that a first wordline of the plurality of wordlines 756 is located between a first through array via of the through array vias 770 and second through array via of the through array vias 770 in the shared wordline access structure area 780.

Additionally, or alternatively, the plurality of through array vias 770 and the plurality of wordlines 756 are comingled so that a first row of the plurality of wordlines 756 is located between a first row of the through array vias 770 and second row of the through array vias 770 in the shared wordline access structure area 780.

In some implementations, the plurality of wordlines 756 penetrate through the plurality of decks in a variable depth pattern (e.g., a V shaped depth pattern or the like (as illustrated here) while the plurality of through array vias 770 penetrate through the plurality of decks at a common depth.

In operation, wordline (WL) contact holes undergo a sidewall process. After the hole reactive-ion etching (RIE), Si oxide (or the like) will be deposited on the bottom and sidewall of the hole, then the bottom oxide will be removed by the following RIE (e.g., in a breakthrough step). Then the metal for the wordline contacts will be filled. The Si oxide sidewall will act as an insulating material between a WL contact and other WLs, and will typically not be affected by the oxide thickness variation. Therefore, as long as there is an oxide film thick enough to prevent the WL-WL short and control the oxide thickness fluctuation, this structure is robust to WL-WL short-circuits.

Conversely, referring to FIG. 7A, a typical staircase based layout for existing multi-deck non-volatile memory structure 700 is illustrated. As illustrated WL contacts are formed in a staircase area, and TAVs are separated physically from WL contacts in a separate area. The separation of WL contacts and TAVs typically makes metal routing between them challenging. As the implementations described herein may not form staircase structure, WL contacts can be placed anywhere in WL hookup area, as shown in FIG. 7B.

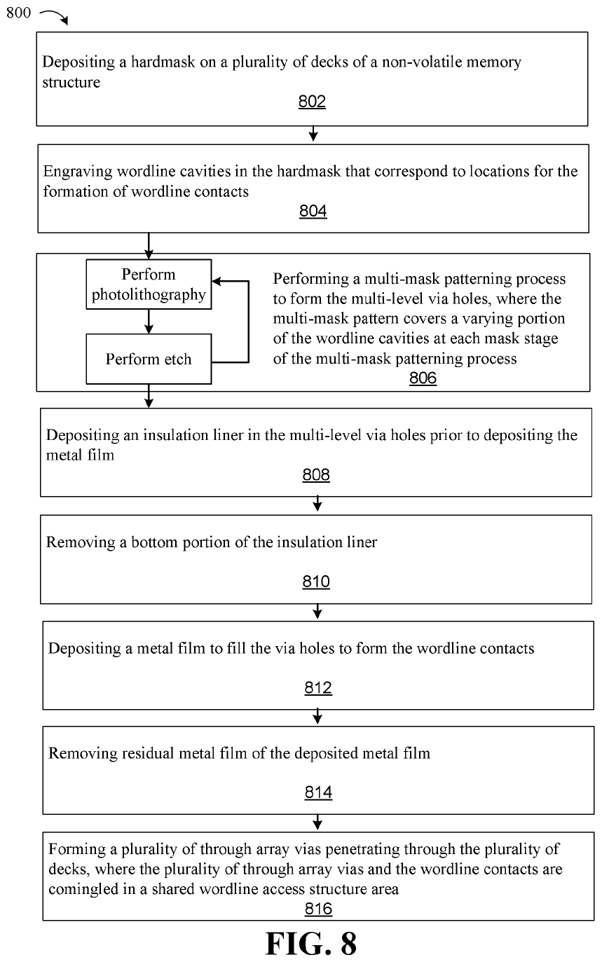

FIG. 8 is a flowchart of an example of a method 800 of forming a memory device according to an embodiment. The method 800 may generally be implemented to form a memory device, such as, for example, the memory device 550 (FIG. 5B), memory device 650 (FIG. 6), memory device 750 (FIG. 7B), already discussed.

Illustrated processing block 802 provides for depositing a hardmask on a plurality of decks of a non-volatile memory structure. For example, depositing such a hardmask may be performed prior to forming multi-level via holes, as will be described in greater detail below.

Illustrated processing block 804 provides for engraving wordline cavities in the hardmask. For example, engraving of wordline cavities in the hardmask may be done to correspond to locations for the formation of desired wordline contacts.

Illustrated processing block 806 provides for preforming a multi-mask patterning process to form the multi-level via holes. For example, the multi-mask pattern may cover a varying portion of the wordline cavities at each mask stage of the multi-mask patterning process. In some examples, the multi-mask patterning process further comprises preforming the multi-mask patterning process for a number of iterations determined by a number of wordlines requiring access. For example, additional process resist formations and etchings will repeat till all wordlines are contacted. In general, N (N=1, 2, 3, . . . ) masks are needed to form 2^{N} WL or less contacts. For example, to make 100 WL contacts of 100 WL layers, this lithography and etch process may be repeated 7 times.

In some implementations, the multi-mask patterning process further includes forming a first, second, and third, etc. process resist. For example,, such a first process resist may include forming the first process resist to cover a first half of the wordline cavities, where the first process resist has a first pattern that only covers every other wordline cavity; etching a first uncovered half of the wordline cavities; and removing the first process resist.

Additionally, or alternatively, such a second process resist may include forming the second process resist to cover a second half of the wordline cavities, where the second process resist has a second pattern that only covers every other quad of wordline cavities; etching a second uncovered half of the wordline cavities; and removing the second process resist.

Additionally, or alternatively, such a third process resist may include forming the third process resist to cover a third half of the wordline cavities, where the third process resist has a third pattern that only covers every other quad of wordline cavities; etching a third uncovered half of the wordline cavities; and removing the third process resist.

Illustrated processing block 808 provides for depositing an insulation liner in the multi-level via holes. For example, depositing such an insulation liner in the multi-level via holes may be done prior to depositing a metal film to fill the via holes.

Illustrated processing block 810 provides for removing a bottom portion of the insulation liner.

Illustrated processing block 812 provides for depositing a metal film to fill the via holes to form the wordline contacts.

Illustrated processing block 814 provides for removing residual metal film of the deposited metal film.

Illustrated processing block 816 provides for forming a plurality of through array vias penetrating through the plurality of decks. For example, the plurality of through array vias and the wordline contacts may be comingled in a shared wordline access structure area.

For example, the plurality of through array vias and the wordline contacts are comingled so that a first wordline of the wordline contacts is located between a first through array via of the through array vias and second through array via of the through array vias in the shared wordline access structure area.

Additionally, or alternatively, the plurality of through array vias and the wordline contacts are comingled so that a first row of the wordline contacts is located between a first row of the through array vias and second row of the through array vias in the shared wordline access structure area.

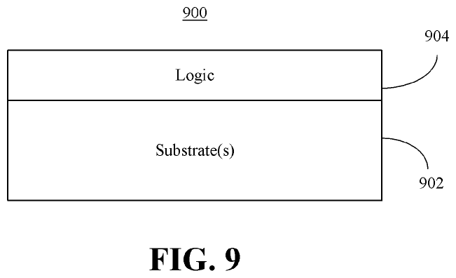

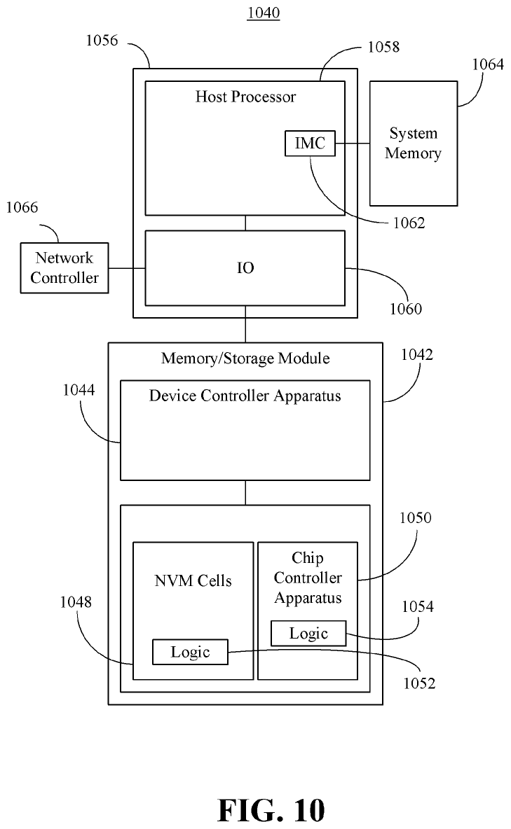

Additional details regarding the various implementations of method 800 are discussed below with regard to FIGS. 9 and 10.

FIG. 9 shows a semiconductor apparatus 900 (e.g., chip, die, and/or package). The illustrated apparatus 900 includes one or more substrates 902 (e.g., silicon, sapphire, gallium arsenide) and logic 904 (e.g., transistor array and other integrated circuit/IC components) coupled to the substrate(s) 902. In an embodiment, the logic 904 implements one or more aspects of the memory device 550 (FIG. 5B), memory device 650 (FIG. 6), memory device 750 (FIG. 7B) already discussed.

In one example, the logic 904 includes transistor channel regions that are positioned (e.g., embedded) within the substrate(s) 902. Thus, the interface between the logic 904 and the substrate 902 may not be an abrupt junction. The logic 904 may also be considered to include an epitaxial layer that is grown on an initial wafer of the substrate 902.

Turning now to FIG. 10, a performance-enhanced computing system 1040 is shown. In the illustrated example, a solid state drive (SSD) 1042 includes a device controller apparatus 1044 that is coupled to a NAND 1046. The illustrated NAND 1046 includes a memory device 1048 having a set of multi-level NVM cells and logic 1052 (e.g., transistor array and other integrated circuit/IC components coupled to one or more substrates containing silicon, sapphire and/or gallium arsenide), and a chip controller apparatus 1050 that includes logic 1054. The logic 1054 may include one or more of configurable or fixed-functionality hardware.

The illustrated system 1040 also includes a system on chip (SoC) 1056 having a host processor 1058 (e.g., central processing unit/CPU) and an input/output (I/O) module 1060. The host processor 1058 may include an integrated memory controller 1062 (IMC) that communicates with system memory 1064 (e.g., RAM dual inline memory modules/DIMMs). The illustrated IO module 1060 is coupled to the SSD 1042 as well as other system components such as a network controller 1066.

In some embodiments, the NAND 1046 implements one or more aspects of the memory device 550 (FIG. 5B), memory device 650 (FIG. 6), memory device 750 (FIG. 7B) already discussed. For example, the NAND 1046 is implementable as a multi-deck non-volatile memory structure comprising a plurality of decks coupled to the device controller apparatus 1044 (e.g., a memory controller).

### Additional Notes and Examples

Example 1 includes a memory device comprising a memory array and a memory block coupled to the memory array The memory block comprising a plurality of wordlines penetrating through a plurality of decks of a non-volatile memory structure; and a plurality of through array vias penetrating through the plurality of decks, where the plurality of through array vias and the plurality of wordlines are comingled in a shared wordline access structure area.

Example 2 includes the memory device of example 1, where the plurality of through array vias and the plurality of wordlines are comingled so that a first wordline of the plurality of wordlines is located between a first through array via of the through array vias and second through array via of the through array vias in the shared wordline access structure area.

Example 3 includes the memory device of example 1, where the plurality of through array vias and the plurality of wordlines are comingled so that a first row of the plurality of wordlines is located between a first row of the through array vias and second row of the through array vias in the shared wordline access structure area.

Example 4 includes the memory device of any one of Examples 1 to 3, where the plurality of wordlines penetrate through the plurality of decks in a variable depth pattern while the plurality of through array vias penetrate through the plurality of decks at a common depth.

Example 5 includes the memory device of any one of Examples 1 to 4, where the shared wordline access structure area is free of a 3D NAND staircase structure.

Example 6 includes the memory device of any one of Examples 1 to 5, where the memory device comprises 3D NAND.

Example 7 includes a system comprising:
a memory controller; and
a multi-deck non-volatile memory structure coupled to the memory controller, the multi-deck non-volatile memory structure comprising a plurality of decks, multi-deck non-volatile memory structure comprising:
a plurality of wordline contacts penetrating through a plurality of decks; and
a plurality of through array vias penetrating through the plurality of decks, where the plurality of through array vias and the plurality of wordline contacts are comingled in a shared wordline access structure area.

Example 8 includes the system of example 7, where the plurality of through array vias and the plurality of wordline contacts are comingled so that a first wordline contact of the plurality of wordline contacts is located between a first through array via of the through array vias and second through array via of the through array vias in the shared wordline access structure area.

Example 9 includes the system of example 7, where the plurality of through array vias and the plurality of wordline contacts are comingled so that a first row of the plurality of wordline contacts is located between a first row of the through array vias and second row of the through array vias in the shared wordline access structure area.

Example 10 includes the system of any one of Examples 7 to 9, where the plurality of wordline contacts penetrate through the plurality of decks in a variable depth pattern while the plurality of through array vias penetrate through the plurality of decks at a common depth.

Example 11 includes the system of any one of Examples 7 to 10, where the shared wordline access structure area is free of a 3D NAND staircase structure.

Example 12 includes the system of any one of Examples 7 to 11, where the multi-deck non-volatile memory structure comprises 3D NAND.

Example 13 includes a method comprising: forming multi-level via holes penetrating through a plurality of decks of a non-volatile memory structure of a memory device based on wordline contact patterning; and depositing a metal film to fill the via holes to form wordline contacts.

Example 14 includes the method of example 13, further comprising: depositing an insulation liner in the multi-level via holes prior to depositing the metal film.

Example 15 includes the method of example 14, further comprising: removing a bottom portion of the insulation liner.

Example 16 includes the method of any one of Examples 13 to 15, further comprising: depositing a hardmask on the plurality of decks of a non-volatile memory structure prior to forming the multi-level via holes; engraving wordline cavities in the hardmask that correspond to locations for formation of the wordline contacts; and preforming a multi-mask patterning process to form the multi-level via holes, where a multi-mask pattern covers a varying portion of the wordline cavities at each mask stage of the multi-mask patterning process.

Example 17 includes the method of example 16, where the multi-mask patterning process further comprises preforming the multi-mask patterning process for a number of iterations determined by a number of wordlines requiring access, the multi-mask patterning process further comprising: forming a first process resist to cover a first half of the wordline cavities, where the first process resist has a first pattern that only covers every other wordline cavity; etching a first uncovered half of the wordline cavities; removing the first process resist; forming a second process resist to cover a second half of the wordline cavities, where the second process resist has a second pattern that only covers every other pair of wordline cavities; etching a second uncovered half of the wordline cavities; removing the second process resist; forming a third process resist to cover a third half of the wordline cavities, where the third process resist has a third pattern that only covers every other quad of wordline cavities; etching a third uncovered half of the wordline cavities; and removing the third process resist.

Example 18 includes the method of any one of Examples 13 to 17, further comprising: forming a plurality of through array vias penetrating through the plurality of decks, where the plurality of through array vias and the wordline contacts are comingled in a shared wordline access structure area.

Example 19 includes the method of example 18, where the plurality of through array vias and the wordline contacts are comingled so that a first wordline of the wordline contacts is located between a first through array via of the through array vias and second through array via of the through array vias in the shared wordline access structure area.

Example 20 includes the method of example 18, where the plurality of through array vias and the wordline contacts are comingled so that a first row of the wordline contacts is located between a first row of the through array vias and second row of the through array vias in the shared wordline access structure area.

Example 21 includes an apparatus comprising means for performing the method of any one of Examples 13 to 20.

Example 22 includes a machine-readable storage comprising machine-readable instructions, which when executed, implement a method or realize an apparatus as claimed in any preceding claim.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

1. A memory device comprising:
a memory array; and
a memory block coupled to the memory array, the memory block comprising:
a plurality of wordlines penetrating through a plurality of decks of a non-volatile memory structure; and
a plurality of through array vias penetrating through the plurality of decks, wherein the plurality of through array vias and the plurality of wordlines are comingled in a shared wordline access structure area.

2. The memory device of claim 1, wherein the plurality of through array vias and the plurality of wordlines are comingled so that a first wordline of the plurality of wordlines is located between a first through array via of the through array vias and second through array via of the through array vias in the shared wordline access structure area.

3. The memory device of claim 1, wherein the plurality of through array vias and the plurality of wordlines are comingled so that a first row of the plurality of wordlines is located between a first row of the through array vias and second row of the through array vias in the shared wordline access structure area.

4. The memory device of claim 1, wherein the plurality of wordlines penetrate through the plurality of decks in a variable depth pattern while the plurality of through array vias penetrate through the plurality of decks at a common depth.

5. The memory device of claim 1, wherein the shared wordline access structure area is free of a 3D NAND staircase structure.

6. The memory device of claim 1, wherein the memory device comprises 3D NAND.

7. A system comprising:
a memory controller; and
a multi-deck non-volatile memory structure coupled to the memory controller, the multi-deck non-volatile memory structure comprising a plurality of decks, multi-deck non-volatile memory structure comprising:
a plurality of wordline contacts penetrating through a plurality of decks; and
a plurality of through array vias penetrating through the plurality of decks, wherein the plurality of through array vias and the plurality of wordline contacts are comingled in a shared wordline access structure area.

8. The system of claim 7, wherein the plurality of through array vias and the plurality of wordline contacts are comingled so that a first wordline contact of the plurality of wordline contacts is located between a first through array via of the through array vias and second through array via of the through array vias in the shared wordline access structure area.

9. The system of claim 7, wherein the plurality of through array vias and the plurality of wordline contacts are comingled so that a first row of the plurality of wordline contacts is located between a first row of the through array vias and second row of the through array vias in the shared wordline access structure area.

10. The system of claim 7, wherein the plurality of wordline contacts penetrate through the plurality of decks in a variable depth pattern while the plurality of through array vias penetrate through the plurality of decks at a common depth.

11. The system of claim 7, wherein the shared wordline access structure area is free of a 3D NAND staircase structure.

12. The system of claim 7, wherein the multi-deck non-volatile memory structure comprises 3D NAND.

13. A method comprising:
forming multi-level via holes penetrating through a plurality of decks of a non-volatile memory structure of a memory device based on wordline contact patterning; and
depositing a metal film to fill the via holes to form wordline contacts.

14. The method of claim 13, further comprising:
depositing an insulation liner in the multi-level via holes prior to depositing the metal film.

15. The method of claim 14, further comprising:
removing a bottom portion of the insulation liner.

16. The method of claim 13, further comprising:
depositing a hardmask on the plurality of decks of a non-volatile memory structure prior to forming the multi-level via holes;
engraving wordline cavities in the hardmask that correspond to locations for formation of the wordline contacts; and
preforming a multi-mask patterning process to form the multi-level via holes, wherein a multi-mask pattern covers a varying portion of the wordline cavities at each mask stage of the multi-mask patterning process.

17. The method of claim 16, wherein the multi-mask patterning process further comprises preforming the multi-mask patterning process for a number of iterations determined by a number of wordlines requiring access, the multi-mask patterning process further comprising:
forming a first process resist to cover a first half of the wordline cavities, wherein the first process resist has a first pattern that only covers every other wordline cavity; etching a first uncovered half of the wordline cavities;
removing the first process resist;
forming a second process resist to cover a second half of the wordline cavities, wherein the second process resist has a second pattern that only covers every other pair of wordline cavities;
etching a second uncovered half of the wordline cavities;
removing the second process resist;
forming a third process resist to cover a third half of the wordline cavities, wherein the third process resist has a third pattern that only covers every other quad of wordline cavities;
etching a third uncovered half of the wordline cavities; and
removing the third process resist.

18. The method of claim 13, further comprising:
forming a plurality of through array vias penetrating through the plurality of decks, wherein the plurality of through array vias and the wordline contacts are comingled in a shared wordline access structure area.

19. The method of claim 18, wherein the plurality of through array vias and the wordline contacts are comingled so that a first wordline of the wordline contacts is located between a first through array via of the through array vias and second through array via of the through array vias in the shared wordline access structure area.

20. The method of claim 18, wherein the plurality of through array vias and the wordline contacts are comingled so that a first row of the wordline contacts is located between a first row of the through array vias and second row of the through array vias in the shared wordline access structure area.
